(19) United States
(12) Patent Application Publication
(10) Pub. No.: US 2009/0098715 A1
(43) Pub. Date: Apr. 16, 2009

(54) Process for manufacturing silicon wafers for solar cell

(75) Inventors: Genmao Chen, Toronto (CA); Jiang Peng, Suzhou (CN)

Correspondence Address: FULWIDER PATTON LLP, HOWARD HUGHES CENTER, 6060 CENTER DRIVE, TENTH FLOOR, LOS ANGELES, CA, 90045, US

(73) Assignee: CSI Cells Co., Ltd., Suzhou (CN)

(21) Appl. No.: 12/286,943

(22) Filed: Oct. 3, 2008

(30) Foreign Application Priority Data
Oct. 8, 2007 (CN) 200710132842.2

(51) Int. Cl. H01L 21/20

(52) U.S. Cl. 438/478; 257/E21.09

(57) ABSTRACT

A process for manufacturing silicon wafers for solar cell is disclosed wherein one first breaks the refined metallurgical silicon, then remove visible impurities, then performs chemical cleaning and then places the silicon into a crystal growing furnace. Gallium or gallium phosphide is added to the silicon, where the concentration of gallium atoms should be in the range from 5 ppma to 14 ppma. Crystal growth is initiated, followed by subdivision and inspection after the crystal rods or crystal bars have grown, yielding the desired silicon wafers. With this solution, the refined metallurgical silicon can be used for manufacturing of solar cells, so as to reduce the cost of materials, and it is conducive to the universal application of silicon solar cells.

### CROSS-REFERENCES TO RELATED APPLICATIONS

This application claims priority from Chinese Patent Application No. 200710132842.2, filed Oct. 8, 2007.

### BACKGROUND

This invention relates to a process for manufacturing silicon wafers for solar cells, and more particularly to a process for manufacturing low cost silicon wafers for solar cells with refined metallurgical silicon.

With the continued development of modern industry, energy demand is growing. Because conventional energy sources release a lot of carbon dioxide when being used, resulting in the global “greenhouse effect,” countries around the world are trying to reduce their dependence on conventional energy sources and accelerate the development of renewable energy sources. As one of the best renewable energy sources, the use of solar energy has drawn high attention. Although the research on solar cells has been going on for 30 to 40 years, only in recent years have solar cells been put into large-scale applications. The rapid development of the solar energy industry has greatly reduced its manufacturing costs, but at the same time, the cost of silicon materials for solar cells is rising rapidly, which makes the overall cost of the application of solar cells still high.

The purity of conventional silicon material for making solar cells should be more than 7N, but materials of such purity are costly. How to manufacture solar cells using silicon wafers with lower purity has become a focus of research. The cost of refined metallurgical silicon is relatively low, but the impurity levels of phosphorus and boron are comparatively high. When this material is used for making solar cells, the boron, as an acceptor impurity, would make the silicon wafer to appear a P-type when the contents of boron is too high. On the other hand, when the content of phosphorus which is a donor impurity is high, the silicon will appear to be N-type. As the segregation coefficient of boron in silicon is 0.8 while that of phosphorus is 0.33, boron would be distributed evenly in the silicon after the crystal growing is finished. However, the distribution of phosphorus will be at higher levels at the back-end of silicon rods (bars) which makes the silicon rods (bars) showing a reversed type in the back-end. This portion of material can not be used for making solar cells, which results in a low utilization of material.

If the type-reversing point can be made to be nearer to the end of silicon rods (bars) during the course of growth of crystal, that is, to increase the utilization of material, then it will greatly reduce the material cost of solar cell.

### SUMMARY OF THE INVENTION

The object of the present invention is to provide a process for manufacturing low-cost silicon wafers for solar cells, which improves the utilization ratio of the length of the silicon crystal rods (bars) through reprocessing of the refined metallurgical silicon, so as to reduce the material cost of solar cells.

This object is achieved according to the technical solution described below, wherein a process for manufacturing silicon wafers for solar cells is described. The process involves first breaking the refined metallurgical silicon that has a relatively high level of phosphorus and boron, removing visible impurities (such as interlayer impurities), performing chemical cleaning, and then heating the silicon in a crystal growing furnace while adding gallium or gallium phosphide to the silicon where the concentration of gallium atoms should be in the range from 5 ppma to 14 ppma, followed by subdivision and inspection after the crystal rods or crystal bars have grown.

The step of breaking the refined metallurgical silicon and removing impurities are existing skills which including the following typical steps: \textcircled{1} sorting and removing impurities visible to the unaided eye; \textcircled{2} ultrasonic cleaning; and \textcircled{3} chemical cleaning (cleaning in the mixture of nitric acid and hydrofluoric acid to remove the surface impurities that may be contained). The step of the growth of crystal rods (bars) include heating it in a crucible with an argon shield, where the temperature exceeds the melting point of silicon at 1412° C. At this point, the silicon is melting, and in this process, gallium is evenly spread into the liquid silicon. Because the segregation coefficient of gallium in silicon is 0.008, the impact of the concentration of gallium as an impurity to the front end of crystal rods (bars) can be negligible, but in the back end of the crystal rods (bars) it shows an exponential increase. Moreover, because gallium is an acceptor impurity like boron, the increase of gallium can compensate for the high concentration of phosphorus at the back end of crystal rods (bars), making the type reversing point of crystal rods (bars) shift to the back end and thereby improves the utilization rate of crystal rods (bars).

According to the different requirement of the production of solar cells, said crystal rods growth may be conducted by the pulling of silicon crystals process and the wafer obtained would be mono-crystalline silicon wafer. Or, said crystal rods growth may be polycrystalline silicon casting process and the wafer obtained would be a polycrystalline silicon wafer. The manufacturing processes of mono-crystalline silicon and polycrystalline silicon are both existing technologies.

Using the process of the present invention, several shortcomings of the prior art are eliminated. In this invention, the gallium which has lower segregation coefficient in silicon but can act as acceptor impurity as boron is added in the silicon crystal before the silicon rod (bar) is grown, so that it reduces the tendency that the donor impurity would increase rapidly at the back end of the rod (bar). This feature makes the type reversing point shift to the very end of crystal silicon rod (bar), and improves the utilization of material. Therefore, the refined metallurgical silicon (5˜6 N) can be used for manufacturing of solar cells, reaching a higher material utilization and reducing the cost of materials, and it is conducive to the universal application of silicon solar cells.

### BRIEF DESCRIPTION OF THE DRAWINGS

FIG. 1 is the process flow diagram of Example 1 of this invention;

FIG. 2 is the distribution diagram of net impurity concentration after gallium is added to the mono-crystalline silicon in Example 1; and

FIG. 3 is the distribution diagram of net impurity concentration without gallium being added to the mono-crystalline silicon in Comparison Example 1.

### DETAILED DESCRIPTION OF THE PREFERRED EMBODIMENTS

This invention will be best understood with reference to the following description of example embodiments.

### Example 1

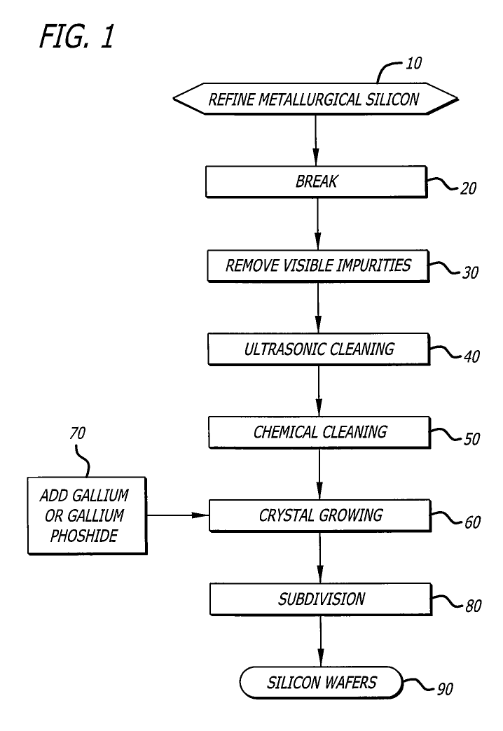

According to the flow diagram of FIG. 1, a process for manufacturing silicon wafers for solar cells is described. In a first step 10, a refining of metallurgical silicon is conducted to yield a sample having a purity on the order of 5N. In the second step 20, the refined metallurgical silicon is broken into units of the appropriate size. If the incoming materials have high interlayer impurities, then the diameter of silicon pieces after breaking should be not more than 4 cm. After preliminary selection to remove visible impurities in step 30, the pieces are put into an ultrasonic cleaner in step 40 for cleaning. Thereafter, the silicon is moved into a mixture of nitric acid and hydrofluoric acid in step 50 order to wash away the surface impurities, and then put them into high-purity quartz crucible. During this step, gallium is added with an atomic concentration of 12.0 ppma in step 70. The quartz crystal crucible is then placed in a graphite crucible in the crystal furnace, and the furnace is pumped to a vacuum. Argon is introduced as the protection gas, and the furnace is heated to a temperature beyond the melting point of silicon to melt the raw materials in the crucible, while keeping the temperature so that the temperature and flow state of liquid silicone become stable and the distribution of gallium become even. Then crystal growth is conducted in step 60 to get mono-crystalline silicon rods. In the above processes, said crystal growth includes inserting seed crystal, dash process to form the crystal neck, forming crystal shoulder to get the desired diameter, growing the crystal with a constant diameter, forming the end cone, and so on as is customary in the conventional method. Then the silicon bar is subdivided in step 80 for processing and inspection to get mono-crystalline silicon wafers in step 90.

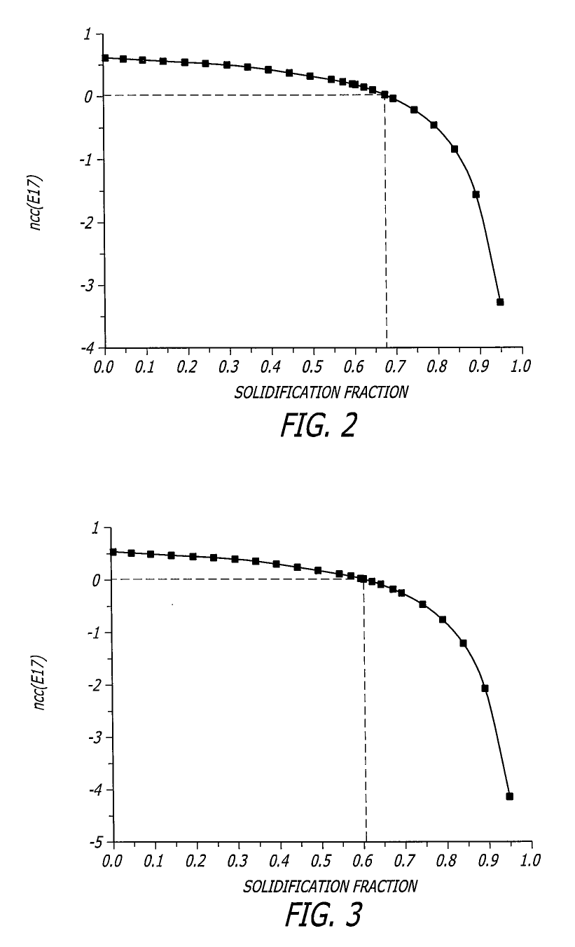

In this example, the concentrations of boron and phosphorus contained in the silicon wafer obtained above are 4.15 ppma and 6.08 ppma, respectively. From FIG. 2, after the above treatment, the length of usable silicon rod is 68%.

The silicon wafer made according to the foregoing example can be made into mono-crystalline silicon solar cells using a normal process. Tests show that these solar cells have an average photoelectric conversion efficiency of 14.5%. Comparison Example 1:

To compare the results of the present invention without step 70, a batch of silicon cells using poly-crystalline silicon with the same low purity as that used in Example 1 were prepared, treating it with the same process as in Example 1 but not having gallium added, to get the mono-crystalline silicon wafer. The graph of FIG. 3 shows that, using the same technology but not having gallium added, the length of usable silicon rod is 61%. Thus, the length of usable silicon rod in Example 1 is 7% more than that in the Comparison Example 1 without the gallium step.

### Example 2

A process for manufacturing silicon wafers for solar cells is disclosed where the refined metallurgical silicon is subdivided into an the appropriate size as discussed in Example 1, followed by a preliminary selection to remove visible impurities. The silicon pieces are then put into an ultrasonic cleaner for cleaning, and deposited into a mixture of nitric acid and hydrofluoric acid in order to wash away the surface impurities. The washed silicon pieces are transferred to a high-purity quartz crucible, and gallium with atomic concentration of 12.2 ppma is added to the crucible. The quartz crystal crucible is placed into a heat exchanging platform (polycrystalline growing furnace), and the furnace is pumped to 0.05˜0.1 mbar pressure and argon is added as the protection gas. Keeping a pressure of 400˜600 mbar in the furnace, it is heated slowly up to 1200˜1300° C. for a duration of 4 to 5 hours, followed by an increase in the heating power gradually up to 1500° C. until the silicon materials begin to melt. As this melting temperature is maintained, the silicon completely melts over the course of 9 to 12 hours, whereupon the heating power may be reduced until the temperature is close to the melting point of silicon. Then the quartz crucible is moved gradually down or the heat insulation device is moved gradually up so that the temperature goes down from the bottom of melted material to the top of it; the crystal silicon will form from the bottom and grow up in a column shape, and during the growing process, the interface of solid and liquid should be kept as horizontal as possible until the whole growing process is completed which requires a duration of 20 to 22 hours. The temperature is kept close to the melting point of silicon for 2 to 4 hours as annealing occurs, and finally the material is cooled down and argon is introduced into the furnace until it reaches normal atmospheric pressure, yielding the poly-crystalline silicon bar. The bar is cut for processing and inspection to get poly-crystalline silicon wafer.

The concentrations of boron and phosphorus contained in the silicon wafer obtained above are 4.21 ppma and 6.17 ppma respectively. After the above treatment, the length of utilized silicon rod is 67%. The silicon wafer made according to this Example can be made into polycrystalline silicon solar cells with a normal process. Tests show that these solar cells have an average photoelectric conversion efficiency of 13.6%. Depending upon the levels of phosphorus, we may also add gallium phosphide into the raw material of silicon instead of gallium.

### Comparison Example 2

The polycrystalline silicon with the same low purity as that used in Example 2 was used, treating it with the same process as in Example 2 but not having gallium or gallium phosphide added, to produce a poly-crystalline silicon wafer. The results shows that where gallium is not added, even though there are processes of acid cleaning and oriented crystallization to make the impurities tend to keep in a zone, the length of utilized silicon rod is 61% when it is used to make solar cells. In addition, the polycrystalline silicon solar cells manufactured with the poly-crystalline silicon wafer obtained in this comparison example, have a photoelectric conversion efficiency of 13.4% on average. It shows that the length of utilized silicon rod in Example 2 is 6% more than that in the Comparison Example 2.

We claim:

1. A process for manufacturing silicon wafers for solar cells, comprising the steps of:
selecting a sample of metallurgical silicon and removing visible impurities;
chemically cleaning the sample;
growing crystals from said sample in a furnace; and
subdivide and inspect the grown crystals;
wherein the growing step is preceded by adding gallium or gallium phosphide to the sample where a concentration of gallium atoms should be in the range from 5 ppma to 14 ppma.

2. The process of claim 1, wherein said growing crystals is conducted by a pulling of silicon crystals process and a wafer obtained is a mono-crystalline silicon wafer.

3. The process of claim 1, wherein said growing crystals is a polycrystalline silicon casting process and a wafer obtained is a polycrystalline silicon wafer.
